(19) United States
(12) Patent Application Publication
(10) Pub. No.: US 2025/0143152 A1
(43) Pub. Date: May 1, 2025

(54) DISPLAY DEVICE

(71) Applicant: Samsung Display Co., Ltd., Yongin-Si (KR)

(72) Inventors: Ho Ryun CHUNG, Yongin-si (KR); Kook Chol PARK, Yongin-si (KR); Sin Ae PARK, Yongin-si (KR); Se Joong SHIN, Yongin-si (KR); Se Hyung CHO, Yongin-si (KR)

(21) Appl. No.: 18/747,100

(22) Filed: Jun. 18, 2024

(30) Foreign Application Priority Data
Oct. 25, 2023 (KR) 10-2023-0143424

(51) Int. Cl. H10K 59/80; H10K 59/127; H10K 59/38; H10K 102/00

(52) U.S. Cl. CPC H10K 59/8791; H10K 59/127; H10K 59/38; H10K 59/80524; H10K 59/8731; H10K 2102/351

(57) ABSTRACT

A display device includes a pixel electrode disposed on a substrate, a bank layer covering edges of the pixel electrode and defining light emitting areas and a non-light emitting area, a light emitting layer on the pixel electrode and the bank layer, a common electrode on the light emitting layer, a capping layer on the common electrode, a counter substrate facing the substrate, and an optical member on the counter substrate. The capping layer comprises a first capping layer disposed on the common electrode, and a second capping layer disposed on the first capping layer and overlapping the light emitting areas.

### CROSS-REFERENCE TO RELATED APPLICATIONS

This application claims the benefit of Korean Patent Application No. 10-2023-0143424 filed on Oct. 25, 2023, in the Korean Intellectual Property Office, the disclosure of which is incorporated herein in its entirety by reference.

### BACKGROUND

### Field

The present disclosure relates to a display device.

### Description of the Related Art

Our information society increasingly demands various forms of display devices for displaying images. For example, display devices are applied to various electronic devices such as smartphones, digital cameras, notebook computers, navigation devices, and smart televisions.

A display device may be a flat panel display device such as a liquid crystal display device, a field emission display device, or a light emitting display device. The light emitting display devices may include an organic light emitting display device including an organic light emitting element, an inorganic light emitting display device including an inorganic (e.g., semiconductor) light emitting element, and a micro-light emitting display device including a micro-light emitting element.

An organic light emitting element may include two electrodes facing each other and a light emitting layer interposed between the electrodes. The light emitting layer may receive electrons and holes from the two electrodes, where the electrons and holes recombine to generate excitons and emit light, e.g., as the generated excitons change from an excited state to a ground state.

Organic light emitting display devices include organic light emitting elements do not need a light source such as a backlight unit. As a result, organic light emitting display devices have low power consumption, can be made lightweight and thin, and have a wide viewing angle, high luminance and contrast, and fast response speed. Due to these high-quality characteristics, organic emitting display devices are drawing attention as next-generation display devices.

### SUMMARY

Aspects of the present disclosure provide a display device which can reduce the reflectance of external light.

However, aspects of the present disclosure are not restricted to those set forth herein. The above and other aspects of the present disclosure will become more apparent to one of ordinary skill in the art to which the present disclosure pertains by referencing the detailed description below.

According to an aspect of the present disclosure, a display device may comprise a pixel electrode disposed on a substrate, a bank layer covering edges of the pixel electrode and defining light emitting areas and a non-light emitting area, a light emitting layer disposed on the pixel electrode and the bank layer, a common electrode disposed on the light emitting layer, a capping layer disposed on the common electrode, a counter substrate facing the substrate, and an optical member disposed on the counter substrate, wherein the capping layer comprises a first capping layer disposed on the common electrode, and a second capping layer disposed on the first capping layer and overlapping the light emitting areas.

In an embodiment, the first capping layer overlaps the light emitting areas and the non-light emitting area and overlaps the second capping layer.

In an embodiment, a thickness of the first capping layer is 350 to 450 Å.

In an embodiment, a refractive index of each of the first capping layer and the second capping layer is 1.8 to 2.2.

In an embodiment, a thickness of the second capping layer is 150 to 350 Å.

In an embodiment, the first capping layer and the second capping layer comprise different materials.

In an embodiment, the sum of the thicknesses of the first capping layer and the second capping layer in each of the light emitting areas is 600 to 700 Å.

In an embodiment, the first capping layer is disposed under the second capping layer or on the second capping layer.

In an embodiment, the optical member comprises a base layer, a colorant layer disposed on the base layer, and an adhesive layer disposed on the colorant layer.

In an embodiment, the colorant layer transmits light in a wavelength band of 440 to 490 nm, a wavelength band of 510 to 580 nm and a wavelength band of 610 to 660 nm and absorbs light in other wavelength bands.

According to an aspect of the present disclosure, a display device comprises a pixel electrode disposed on a substrate, a bank layer covering edges of the pixel electrode and defining light emitting areas and a non-light emitting area, a light emitting layer disposed on the pixel electrode and the bank layer, a common electrode disposed on the light emitting layer, a capping layer disposed on the common electrode, a counter substrate facing the substrate, and an optical member disposed on the counter substrate, wherein the capping layer comprises a first area overlapping the light emitting areas and a second area overlapping the non-light emitting area, and a thickness of the first area is greater than a thickness of the second area.

In an embodiment, the thickness of the first area is 600 to 700 Å.

In an embodiment, the thickness of the second area is 350 to 450 Å.

In an embodiment, the first area does not overlap the non-light emitting area, and the second area does not overlap the light emitting areas.

In an embodiment, the capping layer comprises an inorganic insulating material or an organic insulating material.

In an embodiment, an upper surface of the capping layer is flat and disposed parallel to the substrate.

According to an aspect of the present disclosure, a display device comprises a pixel electrode disposed on a substrate, a bank layer covering edges of the pixel electrode and defining light emitting areas and a non-light emitting area, a light emitting layer disposed on the pixel electrode and the bank layer, a common electrode disposed on the light emitting layer, a capping layer disposed on the common electrode, a thin-film encapsulation layer disposed on the capping layer, and an optical member disposed on the thin-film encapsulation layer, wherein the capping layer comprises a first area overlapping the light emitting areas and a second area overlapping the non-light emitting area, and a thickness of the first area is greater than a thickness of the second area.

In an embodiment, the thin-film encapsulation layer comprises a first encapsulating inorganic layer disposed on the capping layer, an encapsulating organic layer disposed on the first encapsulating inorganic layer, and a second encapsulating inorganic layer disposed on the encapsulating organic layer.

In an embodiment, the first area does not overlap the non-light emitting area, and the second area does not overlap the light emitting areas.

In an embodiment, the optical member comprises a base layer, a colorant layer disposed on the base layer, and an adhesive layer disposed on the colorant layer, wherein the colorant layer transmits light in a wavelength band of 440 to 490 nm, a wavelength band of 510 to 580 nm and a wavelength band of 610 to 660 nm and absorbs light in other wavelength bands.

In a display device according to an embodiment, a capping layer having different thicknesses in a light emitting area and a non-light emitting area is formed. Therefore, it is possible to reduce the reflection of external light in the non-light emitting area and improve luminous efficiency in the light emitting area.

In addition, since the display device further includes an optical member, the reflection of external light can be reduced, and a polarizing plate can be omitted.

However, the effects of the present disclosure are not restricted to those set forth herein. The above and other effects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings.

FIG. 1 is a schematic plan view of a display device according to an embodiment.

FIG. 2 is a schematic cross-sectional view of the display device according to the embodiment.

FIG. 3 is a schematic layout view illustrating lines included in the display device according to the embodiment.

FIG. 4 is an equivalent circuit diagram of a subpixel according to an embodiment.

FIG. 5 is a schematic cross-sectional view of a subpixel of the display device according to the embodiment.

FIG. 6 is a plan view of the display device according to the embodiment.

FIG. 7 is a cross-sectional view taken along line Q1-Q1′ of FIG. 6.

FIG. 8 is a schematic cross-sectional view illustrating the stacked structure of a non-light emitting area and a light emitting area of the display device according to the embodiment.

FIG. 9 is a cross-sectional view of an optical member according to an embodiment.

FIG. 10 is a graph illustrating the transmittance of the optical member according to the embodiment with respect to wavelength.

FIG. 11 is a cross-sectional view of a display device according to an embodiment.

FIG. 12 is a cross-sectional view of a display device according to an embodiment.

FIG. 13 is a schematic view of a capping layer according to an embodiment.

FIG. 14 is a cross-sectional view of a display device according to an embodiment.

FIG. 15 is a schematic view of a capping layer according to an embodiment.

FIG. 16 is a cross-sectional view of a display device according to an embodiment.

FIGS. 17 and 18 are cross-sectional views illustrating a method of manufacturing a display device according to an embodiment by process.

FIG. 19 shows graphs illustrating wavelength dependence of reflectance from a display device according to an embodiment.

FIG. 20 shows graphs illustrating dependence of relative luminous efficiency-reflected reflectance on wavelength.

FIG. 21 shows a graph illustrating dependence of the amount of reflected light on the thickness of a capping layer.

Use of the same reference symbols in different figures indicates similar or identical items.

### DETAILED DESCRIPTION

The following more fully describes example embodiments with reference to the accompanying drawings, in which the example embodiments are shown. Other embodiments may take different forms, and this disclosure should not be construed as being limited to the example embodiments set forth herein. Rather, the illustrated embodiments are provided so that this disclosure will be thorough and complete, and will fully convey the scope of the of the claims to those skilled in the art.

In the following, a layer referred to as being “on” another layer or substrate may be directly on the other layer or substrate or one or more intervening layers may also be present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of the various embodiments of the present disclosure may be separated or combined with each other, in part or in whole, and technically various interlocking and driving are possible. Each embodiment may be implemented independently of each other or may be implemented together in an association.

Hereinafter, embodiments will be described with reference to the accompanying drawings.

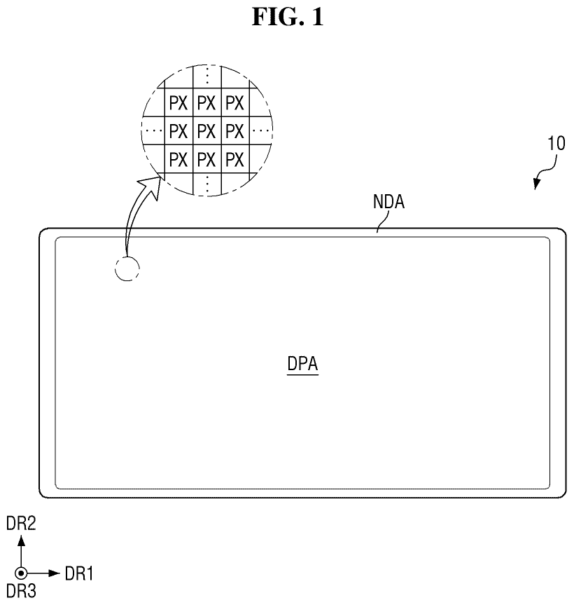

FIG. 1 is a schematic plan view of a display device 10 according to an embodiment.

In the present specification, “above,” “top” and “upper surface” refer to an upward direction from the display device 10, that is, a third direction DR3, and “below,” “bottom” and “lower surface” refer to the direction opposite the third direction DR3. In addition, “left,” “right,” “upper,” and “lower” refer to directions when the display device 10 is seen in plan view. For example, “right” refers to a first direction DR1, “left” refers to the direction opposite the first direction DR1, “upper” refers to a second direction DR2, and “lower” refers to the direction opposite the second direction DR2.

Referring to FIG. 1, the display device 10 may display moving images or still images. The display device 10 may be any electronic device that provides a display screen. Examples of the display device 10 may include televisions, notebook computers, monitors, billboards, Internet of things (IoT) devices, mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, and camcorders, all of which provide a display screen.

The display device 10 may include a display panel that provides a display screen. Examples of the display panel may include inorganic light emitting diode display panels, organic light emitting display panels, quantum dot light emitting display panels, plasma display panels, and field emission display panels. An example including an organic light emitting diode display panel is described below, but the present disclosure is not limited to this case, and other display panels can also be applied as long as the same technical spirit is applicable.

The shape of the display device 10 can be variously modified from the example shown in FIG. 1. For example, the display device 10 may have various shapes such as a horizontally long rectangle, a vertically long rectangle, a square, a quadrilateral with rounded corners (vertices), other polygons, and a circle. The shape of a display area DPA of the display device 10 may also be similar to the overall shape of the display device 10. In FIG. 1, each of the display device 10 and the display area DPA is generally shaped like a horizontal rectangle.

The display device 10 may include the display area DPA and a non-display area NDA. The display area DPA is an area where an image can be displayed, and the non-display area NDA is an area where no image is displayed. The display area DPA may also be referred to as an active area, and the non-display area NDA may also be referred to as an inactive area. The display area DPA may generally occupy the center of the display device 10.

The display area DA may include a plurality of pixels PX. The pixels PX may be arranged in a matrix. Each of the pixels PX may be rectangular or square in plan view. However, the present disclosure is not limited thereto, and each of the pixels PX may also have other shapes such as a rhombus shape which each side being at a non-perpendicular angle with respect adjacent sides. The pixels PX may alternately be of a stripe type or an island type. In addition, each of the pixels PX may include one or more light emitting elements EL, each of which emits light of a specific wavelength band to display a specific color.

The non-display area NDA may be disposed around the display area DPA. The non-display area NDA may entirely or partially surround the display area DPA. The display area DPA may be rectangular, and the non-display area NDA may be disposed adjacent to four sides of the display area DPA. The non-display area NDA may form a bezel of the display device 10. Wiring or circuit drivers in the display device 10 may be located, or external devices may be mounted, in non-display area NDA.

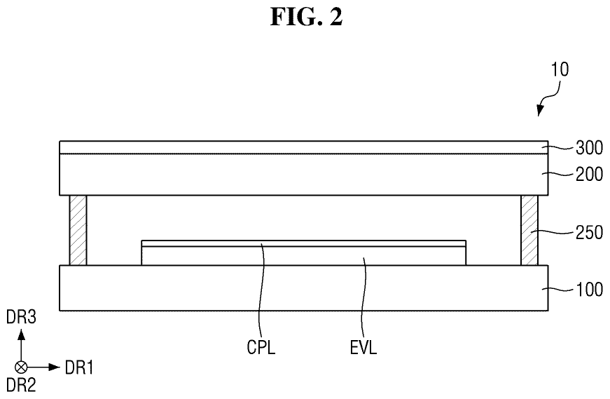

FIG. 2 is a schematic cross-sectional view of the display device 10 according to the embodiment.

Referring to FIG. 2, the display device 10 according to the embodiment of FIG. 1 may include a substrate 100, a counter substrate 200 facing the substrate 100, a sealing member 250 bonding the substrate 100 and the counter substrate 200 together, and an optical member 300 disposed on the counter substrate 200. In addition, the display device 10 may include a display element layer EVL disposed on the substrate 100 and a capping layer CPL disposed on the display element layer EVL.

The substrate 100 may serve as a base for the display device 10. The substrate 100 may be made of a rigid material having rigidity. In some embodiments, the substrate 100 may include, but is not limited to, glass. For example, the substrate 100 may include quartz.

The display element layer EVL may be disposed on the substrate 100 in the third direction DR3. The display element layer EVL may form a display screen and define the display area DPA of the display device 10. That is, an area of element layer EVL on the substrate 100 may be the display area DPA, and an area where the display element layer EVL is not disposed may be the non-display area NDA. The display element layer EVL may overlap the display area DPA in the third direction DR3 and may not overlap the non-display area NDA in the third direction DR3.

The display element layer EVL may include elements and circuits for displaying an image. For example, the display element layer EVL in the display area DPA may include switching elements, pixel circuits, conductive patterns, and light emitting elements, which are described further below. Each of the light emitting elements may include at least one of an organic light emitting diode, a quantum dot light emitting diode, an inorganic material-based micro light emitting diode (e.g., micro LED), and an inorganic material-based nano light emitting diode (e.g., nano LED). For ease of description, a case where the light emitting elements are organic light emitting diodes are described below as an example.

The capping layer CPL may be disposed on the display element layer EVL. The capping layer CPL may cover the display element layer EVL to protect the display element layer EVL and may reduce the reflectance of a non-light emitting area in the display area DPA. The capping layer CPL is described in more detail below.

The counter substrate 200 may be disposed on the substrate 100 and may face the substrate 100. In an embodiment, the counter substrate 200 may be made of transparent material such as glass, plastic, etc. and may be rigid or flexible.

The sealing member 250 may be disposed between the substrate 100 and the counter substrate 200 in the non-display area NDA. The sealing member 250 may be disposed along edges of the substrate 100 and the counter substrate 200 in the non-display area NDA and may surround the display area DPA in plan view. The sealing member 250 may bond the substrate 100 and the counter substrate 200 to each other. In an embodiment, the sealing member 250 may be made of an inorganic or organic material. For example, the sealing member 250 may be made of an inorganic material such as frit or an organic material such as epoxy resin, but the present disclosure is not limited thereto.

The optical member 300 may be disposed on the counter substrate 200. The optical member 300 may reduce the reflection of external light incident on the display device 10 from outside of the display device 10. The optical member 300 is described in more detail below.

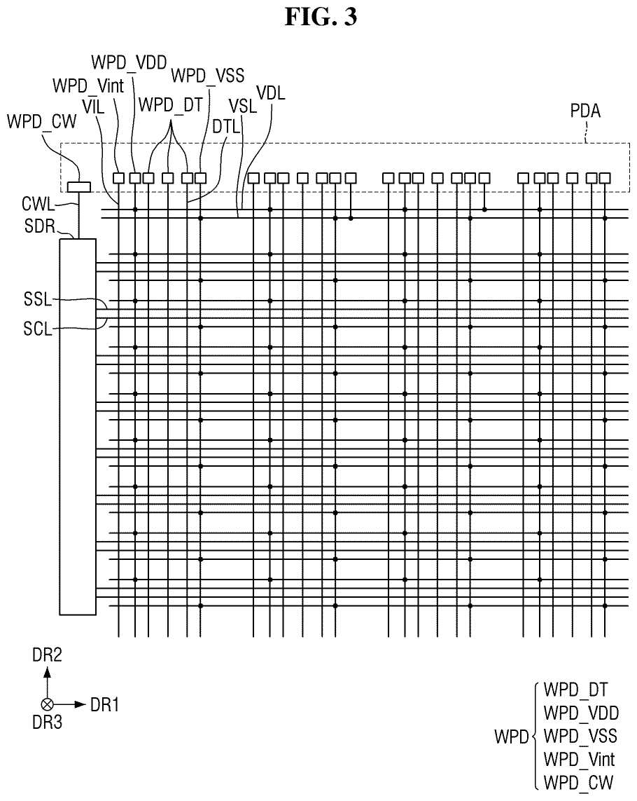

FIG. 3 is a schematic layout view illustrating lines that may be included in the display device 10.

Referring to FIG. 3, the display device 10 may include a plurality of lines. The lines may include scan lines SCL, sensing lines SSL, data lines DTL, initialization voltage lines VIL, a first voltage line VDL, and a second voltage line VSL. In addition, the display device 10 may include other lines not shown in FIG. 3.

The scan lines SCL and the sensing lines SSL may extend in the first direction DR1. The scan lines SCL and the sensing lines SSL may be connected to a scan driver SDR. The scan driver SDR may include a driving circuit. The scan driver SDR may be disposed on a side of the display area DPA in the first direction DR1, but the present disclosure is not limited thereto. The scan driver SDR may be connected to a signal wiring pattern CWL, and at least one end of the signal wiring pattern CWL may form a pad WPD_CW in the non-display area NDA and thus may be connected to an external device.

As used herein, the term ‘connect’ may mean that any one member and another member are connected to each other not only through physical contact but also through another member. In addition, it can be understood that any one part and another part that are connected to each other may be one integrated member. Further, the connection between any one member and another member may be interpreted to include electrical connection through another member in addition to connection through direct contact.

The data lines DTL and the initialization voltage lines VIL may extend in the second direction DR2, which is at an angle with the first direction DR1. The first voltage line VDL and the second voltage line VSL extend in the first direction DR1 and the second direction DR2. In each of the first voltage line VDL and the second voltage line VSL, portions extending in the first direction DR1 and portions extending in the second direction DR2 may made of conductive material disposed on different layers of an integrated circuit structure. The first voltage line VDL and the second voltage line VSL may have a mesh structure covering the entire display area DPA, but the present disclosure is not limited thereto. Each pixel PX of the display device 10 may be connected to at least one data line DTL, an initialization voltage line VIL, the first voltage line VDL, and the second voltage line VSL.

The data lines DTL, the initialization voltage lines VIL, the first voltage line VDL, and the second voltage line VSL may be electrically connected to one or more wiring pads WPD. Each wiring pad WPD may be disposed in a pad area PDA. In an embodiment, wiring pads WPD_DT (hereinafter, referred to as ‘data pads’) of the data lines DTL, wiring pads WPD_Vint (hereinafter, referred to as ‘initialization voltage pads’) of the initialization voltage lines VIL, wiring pads WPD_VDD (hereinafter, referred to as ‘first power pads’) of the first voltage line VDL, and wiring pads WPD_VSS (hereinafter, referred to as ‘second power pads’) of the second voltage line VSL may be disposed in the pad area PDA located on one side of the display area DPA in the second direction DR2. External devices may be mounted on or otherwise connected to the wiring pads WPD. The external devices may, for example, be mounted on the wiring pads through anisotropic conductive films, ultrasonic bonding, or the like.

Each pixel PX or subpixel SPXn (where n is an integer of 1 to 3) of the display device 10 includes a pixel driving circuit. The above-described lines shown in FIG. 3 may transmit driving signals to each pixel driving circuit while passing through or around each pixel PX. Each pixel driving circuit may include a transistor and a capacitor. The number of transistors and capacitors in each pixel driving circuit may differ for different embodiments. According to an example embodiment, the pixel driving circuit of each subpixel SPXn of the display device 10 may have a 3T1C structure including three transistors and one capacitor. Although the pixel driving circuit described in detail below is an example of a 3T1C structure, the present disclosure is not limited thereto, and other various modified pixel structures such as a 2T1C structure, a 7T1C structure, and a 6T1C structure are also applicable.

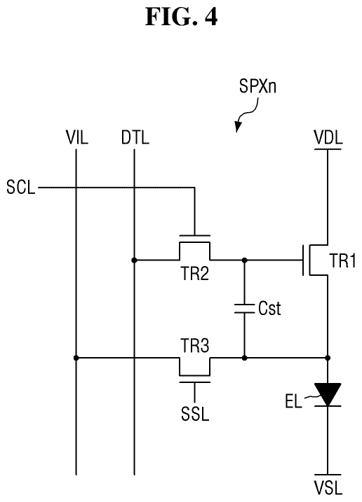

FIG. 4 is an equivalent circuit diagram of a subpixel according to an embodiment.

Referring to FIG. 4, each subpixel SPXn of the display device 10 according to the embodiment includes three transistors TR1 through TR3 and one storage capacitor Cst in addition to a light emitting element EL.

The light emitting element EL emits light having an intensity according to a current supplied to the light emitting element EL through a first transistor TR1. The light emitting element EL includes a first electrode, a second electrode, and at least one light emitting layer disposed between them. The light emitting layer may emit light in a specific wavelength band in response to electrical signals received via the first electrode and the second electrode.

A first end of the light emitting element EL may be connected to a source electrode of the first transistor TR1, and a second end of the light emitting element EL may be connected to a second voltage line VSL to which a low potential voltage (hereinafter, referred to as a second power supply voltage) lower than a high potential voltage (hereinafter, referred to as a first power supply voltage) of a first voltage line VDL is supplied. In addition, the first end of the light emitting element EL may be connected to a source electrode of the third transistor TR3 and to an electrode of the storage capacitor Cst.

The first transistor TR1 adjusts a current flowing from the first voltage line VDL, to which the first power supply voltage is supplied, to the light emitting element EL according to a voltage difference between a gate electrode and the source electrode of the first transistor TR1. For example, the first transistor TR1 may be a driving transistor for driving the light emitting element EL. The first transistor TR1 may have its gate electrode connected to the source electrode of the second transistor TR2, its source electrode connected to the first electrode of the light emitting element EL, and a drain electrode connected to the first voltage line VDL to which the first power supply voltage is applied.

The second transistor TR2 is turned on by a scan signal on a scan line SCL to connect a data line DTL to the gate electrode of the first transistor TR1. The second transistor TR2 may have a gate electrode connected to the scan line SCL, its source electrode connected to the gate electrode of the first transistor TR1, and a drain electrode connected to the data line DTL.

The third transistor TR3 is turned on by a sensing signal on a sensing line SSL to connect an initialization voltage line VIL to the first end of the light emitting element EL. The third transistor TR3 may have a gate electrode connected to the sensing line SSL, a drain electrode connected to the initialization voltage line VIL, and a source electrode connected to the first end of the light emitting element EL or the source electrode of the first transistor TR1.

In an embodiment, each of the transistors TR1 through TR3 is not limited to having source and drain electrodes connected as described above, and electrodes described as being the source (or drain) electrodes may instead be drain (or source) electrodes. In addition, each of the transistors TR1 through TR3 may be formed as a thin-film transistor. In addition, although a case where each of the transistors TR1 through TR3 is an N-type metal oxide semiconductor field effect transistor (MOSFET) are shown in FIG. 4, the present disclosure is not limited thereto. That is, each of the transistors TR1 through TR3 may alternatively be a P-type MOSFET, or some of them may be N-type MOSFETs and the others may be P-type MOSFETs.

The storage capacitor Cst is formed between the gate electrode and the source electrode of the first transistor TR1. The storage capacitor Cst stores a difference between a gate voltage and a source voltage of the first transistor TR1.

The structure of a subpixel SPX of the display device 10 according to the embodiment will now be described in detail with further reference to other drawings.

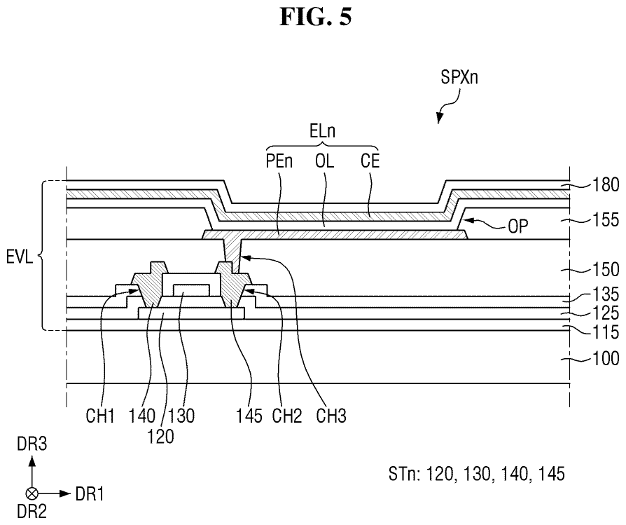

FIG. 5 is a schematic cross-sectional view of a subpixel SPXn of the display device 10 according to an embodiment. FIG. 5 particularly shows in more detail a configuration of the display element layer EVL of the display device 10, which is described above with reference to FIG. 2.

The display device 10 according to the embodiment of FIG. 5 may include the display element layer EVL disposed on the substrate 100.

The display element layer EVL may specifically include a buffer layer 115 disposed on the substrate 100. The buffer layer 115 may be include an inorganic layer that can prevent the penetration of air or moisture. The buffer layer 115 may include a silicon compound, metal oxide, etc. For example, the buffer layer 115 may include silicon oxide, silicon nitride, silicon oxynitride, aluminum oxide, tantalum oxide, hafnium oxide, zirconium oxide, titanium oxide, etc. These materials may be used alone or in combination with each other. The buffer layer 115 may be a single layer or a multilayer layer composed of a stack of different materials.

A switching element STn may be disposed on the buffer layer 115. The switching element STn may include a semiconductor layer 120, a gate electrode 130, a source electrode 140, and a drain electrode 145. The switching element STn may form a portion of a pixel circuit, and each of a plurality of pixel circuits may include one or more such switching elements. FIG. 5 shows one switching element STn disposed in the subpixel SPX of the display device 10, but the subpixel SPX may include multiple switching elements as described above. In one example, the switching element STn may be a driving transistor or a switching transistor of the pixel circuit. In particular, the switching element STn may correspond to the first transistor TR1 of FIG. 4 described above.

The semiconductor layer 120 may be disposed on the buffer layer 115. The semiconductor layer 120 may be partially overlapped by the gate electrode 130 of a first conductive layer, which is described further below.

The semiconductor layer 120 may include polycrystalline silicon, monocrystalline silicon, or an oxide semiconductor. In an embodiment, the semiconductor layer 120 may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

A gate insulating layer 125 may be disposed on the semiconductor layer 120. The gate insulating layer 125 may be disposed on the substrate 100 including the semiconductor layer 120. The gate insulating layer 125 may function as a gate insulating film of the switching element STn.

The gate insulating layer 125 may include a silicon compound, metal oxide, etc. For example, the gate insulating layer 125 may include silicon oxide, silicon nitride, silicon oxynitride, aluminum oxide, tantalum oxide, hafnium oxide, zirconium oxide, titanium oxide, etc. These materials may be used alone or in combination with each other. The gate insulating layer 125 may be a single layer or a multilayer layer composed of a stack of different materials.

The gate electrode 130 may be disposed on the gate insulating layer 125. The gate electrode 130 may overlap a channel region of the semiconductor layer 120 in the third direction DR3 which is a thickness direction. The gate electrode 130 may include metal. For example, the gate electrode 130 may include one or more metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

An interlayer insulating layer 135 may be disposed on the gate electrode 130. The interlayer insulating layer 135 may be disposed on the gate electrode 130 and the gate insulating layer 125. The interlayer insulating layer 135 may function as an insulating film between the gate electrode 130 and other layers disposed on the gate electrode 130. In addition, the interlayer insulating layer 135 may cover the gate electrode 130 to protect the gate electrode 130.

The interlayer insulating layer 135 may include a silicon compound, metal oxide, etc. For example, the interlayer insulating layer 135 may include silicon oxide, silicon nitride, silicon oxynitride, aluminum oxide, tantalum oxide, hafnium oxide, zirconium oxide, titanium oxide, etc. These materials may be used alone or in combination with each other. The interlayer insulating layer 135 may be a single layer or a multilayer layer composed of a stack of different materials.

The source electrode 140 and the drain electrode 145 may be disposed on the interlayer insulating layer 135. The source electrode 140 may be connected to the semiconductor layer 120 through a first contact hole CH1 penetrating the interlayer insulating layer 135 and the gate insulating layer 125. The drain electrode 145 may be connected to the semiconductor layer 120 through a second contact hole CH2 penetrating the interlayer insulating layer 135 and the gate insulating layer 125.

The source electrode 140 and drain electrode 145 may include one or more metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). Each of the source electrode 140 and drain electrode 145 may be a single layer or a multilayer layer.

A via layer 150 may be disposed on the switching element STn. The via layer 150 may provide a flatten surface over the contours or steps thereunder to facilitate formation of a first pixel electrode PE1 on the via layer 150.

The via layer 150 may include an inorganic insulating material or an organic insulating material. For example, the organic insulating material may include polyacrylates resin, epoxy resin, phenolic resin, polyamides resin, polyimides resin, unsaturated polyesters resin, polyphenylenes resin, polyphenylenesulfides resin, or benzocyclobutene (BCB). The via layer 150 may be a single layer or a multilayer layer composed of a stack of different materials.

A light emitting element ELn may be disposed on the via layer 150. The light emitting element ELn may include a pixel electrode PEn, a light emitting layer OL, and a common electrode CE.

The pixel electrode PEn may be disposed on the via layer 150. The pixel electrode PEn may be disposed in a pattern shape in each subpixel SPX (see FIG. 4). The pixel electrode PEn may be an anode of the light emitting element ELn. The pixel electrode PEn may be connected to the drain electrode 145 of the switching element STn through a third contact hole CH3 penetrating the via layer 150.

The pixel electrode PEn may be a reflective electrode. The pixel electrode PEn may have a stacked structure of a material layer having a high work function such as indium tin oxide (ITO), indium zinc oxide (IZO), zinc oxide (ZnO), indium tin zinc oxide (ITZO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is located close to the light emitting layer OL. The pixel electrode PEn may have, but is not limited to, a multilayer structure of ITO/Mg, ITO/MgF, ITO/Ag, or ITO/Ag/ITO.

A bank layer 155 may be disposed on the pixel electrode PEn. The bank layer 155 may include an opening OP that partially exposes the pixel electrode PEn. The bank layer 155 may be made of an organic insulating material or an inorganic insulating material. For example, the bank layer 155 may include at least one of photoresist, polyimide resin, acrylic resin, silicon compound, and polyacrylic resin. The bank layer 155 may display black. The bank layer 155 may include a colorant such as a dye or pigment that displays black. The bank layer 155 displaying black can prevent color mixing of light between adjacent subpixels.

The light emitting layer OL may be disposed on the pixel electrode 160. The light emitting layer OL may further include at least one of a hole injection layer, a hole transport layer, an electron transport layer, and an electron injection layer. The light emitting layer OL may emit red, blue, or green light for each subpixel SPXn.

The common electrode CE may be disposed on the light emitting layer OL and

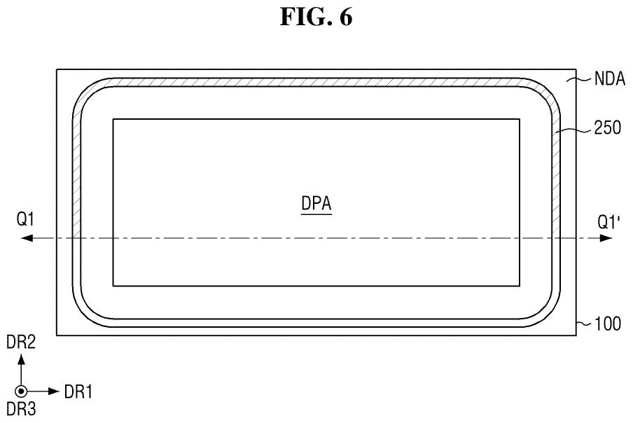

the bank layer 155. The common electrode CE may be disposed on the entire display area DPA (FIG. 6) of the substrate 100. The common electrode CE may be a common electrode disposed across a plurality of subpixels. The common electrode CE may be a cathode of the light emitting element ELn.

The common electrode CE may be translucent or transparent. When the common electrode CE is translucent, the common electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). In addition, when a thickness of the common electrode CE is tens to hundreds of angstroms, the common electrode CE may be translucent.

When the common electrode CE transparent, the common electrode CE may include transparent conductive oxide (TCO). For example, the common electrode CE may include tungsten oxide (WₓOₓ), titanium oxide (TiO₂), indium tin oxide (ITO), indium zinc oxide (IZO), zinc oxide (ZnO), indium tin zinc oxide (ITZO), or magnesium oxide (MgO).

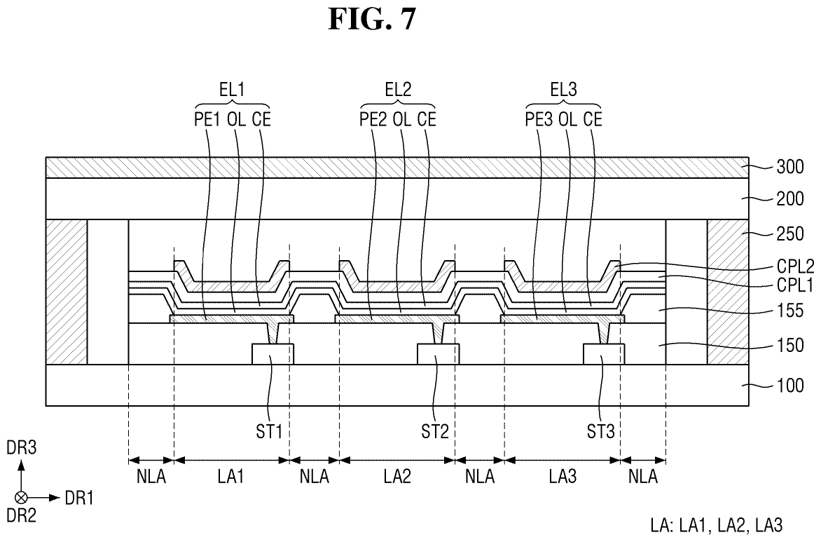

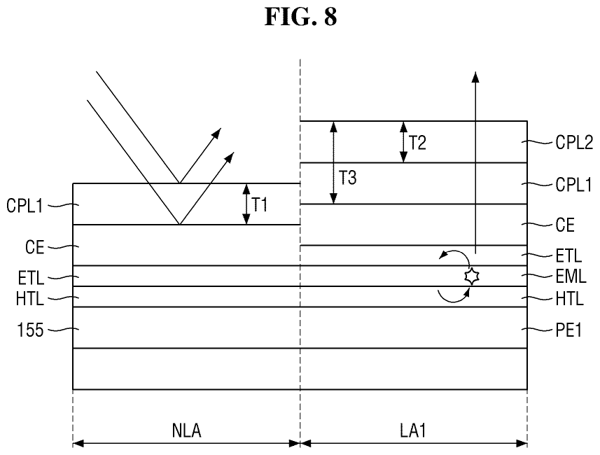

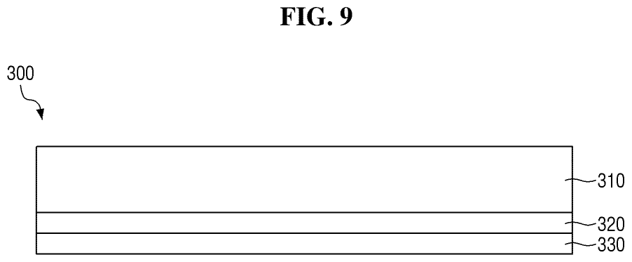

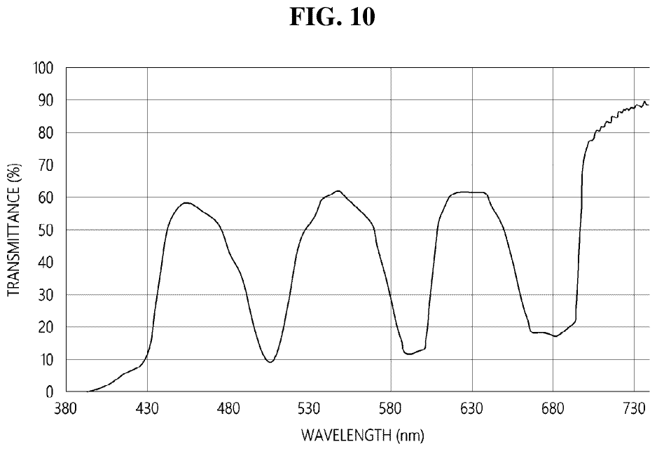

FIG. 6 is a plan view of the display device 10 according to an embodiment. FIG. 7 is a cross-sectional view taken along line Q1-Q1′ of FIG. 6. FIG. 8 is a schematic view illustrating the stacked structure of a non-light emitting area NLA and a light emitting area LA of the display device 10 according to the embodiment. FIG. 9 is a cross-sectional view of an optical member 300 according to an embodiment. FIG. 10 is a graph illustrating the transmittance of the optical member 300 according to the embodiment with respect to wavelength.

Referring to FIGS. 6 through 10, a plurality of light emitting areas LA1 through LA3 and the non-light emitting area NLA may be defined in the substrate 100. The light emitting areas LA1 through LA3 may be areas where light generated by light emitting elements EL1 through EL3 is emitted to the outside, and the non-light emitting area NLA may be an area where light is not emitted to the outside. In an embodiment, a first light emitting area LA1, a second light emitting area LA2, and a third light emitting area LA3 may be sequentially and repeatedly arranged along the first direction DR1 in the display area DPA.

The first light emitting area LA1, the second light emitting area LA2, and the third light emitting area LA3 may have the same width measured in the first direction DR1. For example, the first light emitting area LA1, the second light emitting area LA2, and the third light emitting area LA3 may have the same size or planar area. However, the present disclosure is not limited thereto, and the first light emitting area LA1, the second light emitting area LA2, and the third light emitting area LA3 may also have different widths measured in the first direction DR1. For example, the width of the first light emitting area LA1 may be smaller than the width of the third light emitting area LA3, and the width of the third light emitting area LA3 may be smaller than the width of the second light emitting area LA2.

The light emitting areas LA1 through LA3 may emit light of different colors. In an embodiment, the first light emitting area LA1 may emit light of a first color, the second light emitting area LA2 may emit light of a second color, and the third light emitting area LA3 may emit light of a third color. In an embodiment, the light of the first color may be blue light having a peak wavelength in the range of about 440 to about 480 nm, and the light of the second color may be red light having a peak wavelength in the range of about 610 to about 650 nm. In addition, the light of the third color may be green light having a peak wavelength in the range of about 510 to about 550 nm. However, the present disclosure is not limited thereto, and the light of the second color may also be green light, and the light of the third color may also be red light.

Switching elements ST1 through ST3 may be disposed on the substrate 100. In an embodiment, a first switching element ST1 may overlap the first light emitting area LA1 of the substrate 100, a second switching element ST2 may overlap the second light emitting area LA2, and a third switching element ST3 may overlap the third light emitting area LA3. However, the present disclosure is not limited thereto. In an embodiment, at least any one of the first switching element ST1, the second switching element ST2, and the third switching element ST3 may overlap the non-light emitting area NLA.

The via layer 150 may be disposed on the substrate 100 on which the switching elements ST1 through ST3 are disposed, and the bank layer 155 and the light emitting elements EL1 through EL3 may be disposed on the via layer 150.

Specifically, a first pixel electrode PE1, a second pixel electrode PE2, and a third pixel electrode PE3 may be located on the via layer 150. The first pixel electrode PE1 may be located in the first light emitting area LA1, but at least a portion of the first pixel electrode PE1 may extend to the non-light emitting area NLA. The second pixel electrode PE2 may be located in the second light emitting area LA2, but at least a portion of the second pixel electrode PE2 may extend to the non-light emitting area NLA. The third pixel electrode PE3 may be located in the third light emitting area LA3, but at least a portion of the third pixel electrode PE3 may extend to the non-light emitting area NLA. The first pixel electrode PE1 may penetrate the via layer 150 and may be connected to the first switching element ST1. The second pixel electrode PE2 may penetrate the via layer 150 and may be connected to the second switching element ST2. The third pixel electrode PE3 may penetrate the via layer 150 and may be connected to the third switching element ST3.

The bank layer 155 may be disposed on the first pixel electrode PE1, the second pixel electrode PE2, and the third pixel electrode PE3. The bank layer 155 may define the first light emitting area LA1, the second light emitting area LA2, the third light emitting area LA3, and the non-light emitting area NLA. That is, an area of the first pixel electrode PE1 that the bank layer 155 does not cover may be the first light emitting area LA1. An area of the second pixel electrode PE2 that the bank layer 155 does not cover may be the second light emitting area LA2. In addition, an area of the third pixel electrode PE3 that the bank layer 155 does not cover may be the third light emitting area LA3. In addition, an area where the bank layer 155 is located may be the non-light emitting area NLA.

The light emitting layer OL may be disposed on the first through third pixel electrodes PE1 through PE3 and the bank layer 155. In an embodiment in which the display device 10 is an organic light emitting display device, the light emitting layer OL may include an organic layer including an organic material. The organic layer may include an organic light emitting layer EML and may include a hole transport layer HTL and an electron transport layer ETL as auxiliary layers that assist light emission.

As illustrated in FIG. 8, the organic light emitting layer EML may be patterned to include a separate region in each of the light emitting areas LA1 through LA3, and each region of the organic light emitting layer EML may emit light of a color corresponding to each of the light emitting areas LA1 through LA3. For example, the organic light emitting layer EML disposed in the first light emitting area LA1 may emit blue light, the organic light emitting layer EML disposed in the second light emitting area LA2 may emit red light, and the organic light emitting layer EML disposed in the third light emitting area LA3 may emit green light.

The hole transport layer HTL may be disposed between the organic light emitting layer EML and each of the pixel electrodes PE1 through PE3. However, the present disclosure is not limited thereto, and at least one of a hole injection layer and an electron blocking layer may be further disposed between the organic light emitting layer EML and each of the pixel electrodes PE1 through PE3. The electron transport layer ETL may be disposed between the organic light emitting layer EML and the common electrode CE. However, the present disclosure is not limited thereto, and at least one of a hole blocking layer and an electron injection layer may be further disposed between the organic light emitting layer EML and the common electrode CE. The hole transport layer HTL and the electron transport layer ETL may be common layers continuously disposed in the light emitting areas LA1 through LA3 and the non-light emitting area NLA. For example, the hole transport layer HTL and the electron transport layer ETL may be cover the entire display area DPA (see FIG. 6).

The common electrode CE may be disposed on the light emitting layer OL. The common electrode CE may be a common layer continuously disposed in the light emitting areas LA1 through LA3 and the non-light emitting area NLA.

The first pixel electrode PE1, the light emitting layer OL, and the common electrode CE described above may form a first light emitting element EL1. The second pixel electrode PE2, the light emitting layer OL, and the common electrode CE may form a second light emitting element EL2. The third pixel electrode PE3, the light emitting layer OL, and the common electrode CE may form a third light emitting element EL3. The first light emitting element EL1, the second light emitting element EL2, and the third light emitting element EL3 may be organic light emitting diodes.

The switching elements ST1 through ST3, the via layer 150, the bank layer 155, and the light emitting elements EL1 through EL3 described above may constitute the display element layer EVL (see FIG. 2).

A capping layer CPL may be disposed on the display element layer EVL. The capping layer CPL may protect the display element layer EVL and reduce the reflection of external light incident from the outside by making the external light disappear through destructive interference. The capping layer CPL may include a first capping layer CPL1 and a second capping layer CPL2 disposed on the first capping layer CPL1.

The first capping layer CPL1 may be directly disposed on the display element layer EVL to directly cover the display element layer EVL. The first capping layer CPL1 may overlap each of the light emitting areas LA1 through LA3 and the non-light emitting area NLA of the display element layer EVL. For example, the first capping layer CPL1 may be continuously disposed across the light emitting areas LA1 through LA3 and the non-light emitting area NLA.

The first capping layer CPL1 may include at least one of an inorganic material and an organic material that can protect the top of the display element layer EVL. In some embodiments, the inorganic material may be an inorganic insulating material or an inorganic deposition material, and the organic material may be an organic insulating material or an organic deposition material. In some embodiments, the inorganic material may include, for example, any one or more of silicon nitride, aluminum oxide, titanium oxide, tantalum oxide, zirconium oxide, and niobium oxide. In some embodiments, the organic material may include any one or more of a hole transport layer, a hole injection layer, and an electron transport layer.

The first capping layer CPL1 may have a predetermined thickness to make incident external light disappear through destructive interference. A thickness T1 of the first capping layer CPL1 may be 350 to 450 Å depending on the refractive index of the first capping layer CPL1. External light incident into the display device 10 may be reflected from an upper surface of the first capping layer CPL1, for example, from an interface between the first capping layer CPL1 and an air layer and may be reflected from a lower surface of the first capping layer CPL1, for example, from an interface between the first capping layer CPL1 and the common electrode CE. The light (particularly visible light) reflected from the upper and lower surfaces of the first capping layer CPL1 may destructively interfere with each other to disappear depending on the thickness and refractive index of the first capping layer CPL1. In the current embodiment, the first capping layer CPL1 having a thickness T1 of 350 to 450 Å can reduce the reflection of external light by making the incident external light disappear.

The first capping layer CPL1 may have a refractive index of 1.8 to 2.2 in order to reflect external light and efficiently transmit internally emitted light. The refractive index of the first capping layer CPL1 may preferably be 1.9 to 2.1. In an embodiment, the refractive index of the first capping layer CPL1 may be 2.

The second capping layer CPL2 may be disposed on the first capping layer CPL1. The second capping layer CPL2 may overlap the light emitting areas LA1 through LA3 of the display element layer EVL. Specifically, the second capping layer CPL2 may overlap the first light emitting area LA1, the second light emitting area LA2, and the third light emitting area LA3. The second capping layer CPL2 may not overlap the non-light emitting area NLA of the display element layer EVL. The second capping layer CPL2 may be disposed in the shape of a plurality of islands to correspond to the light emitting areas LA1 through LA3, respectively, and an area between the islands may correspond to the non-light emitting area NLA. In addition, the second capping layer CPL2 may not overlap the bank layer 155.

The second capping layer CPL2 may increase the luminous efficiency of the light emitting elements EL1 through EL3 by increasing the thickness of the capping layer CPL in each of the light emitting areas LA1 through LA3. A thickness T2 of the second capping layer CPL2 may be 150 to 350 Å. A portion of the light emitted from the light emitting layer OL in each of the light emitting elements EL1 through EL3 may be output through the capping layer CPL. Another portion of the light may be reflected from a lower surface of the common electrode CE, an interface between the common electrode CE and the capping layer CPL, and an upper surface of the capping layer CPL and then may be reflected again from each of the pixel electrodes PE1 through PE3 to travel upward. Here, a resonance phenomenon in which various lights of desired wavelengths constructively interfere with each other may occur, and the luminous efficiency may be increased by the resonance phenomenon.

In the current embodiment, the second capping layer CPL2 having a thickness T2 of 150 to 350 Å is formed, and a thickness T3 of the capping layer CPL in each of the light emitting areas LA1 through LA3 may be 600 to 700 Å. The thickness T3 of the capping layer CPL in each of the light emitting areas LA1 through LA3 may be the sum (T1+T2) of the thickness T1 of the first capping layer CPL1 and the thickness T2 of the second capping layer CPL2. If the thickness T3 of the capping layer CPL in each of the light emitting areas LA1 through LA3 may be 600 to 700 Å, a resonance thickness that can cause the resonance phenomenon for light emitted from the light emitting elements EL1 through EL3. Accordingly, the luminous efficiency of each of the light emitting elements EL1 through EL3 can be increased.

The second capping layer CPL2 may include an inorganic material or an organic material. In some embodiments, the inorganic material may be an inorganic insulating material or an inorganic deposition material, and the organic material may be an organic insulating material or an organic deposition material. In some embodiments, the inorganic material may include, for example, any one or more of silicon nitride, aluminum oxide, titanium oxide, tantalum oxide, zirconium oxide, and niobium oxide. In some embodiments, the organic material may include any one or more of acrylic resin, methacrylate resin, polyisoprene, vinyl resin, epoxy resin, urethane resin, cellulose resin, and perylene resin. In an embodiment, the second capping layer CPL2 may include a different material from the first capping layer CPL1. For example, the first capping layer CPL1 and the second capping layer CPL2 may be made of different inorganic materials.

The second capping layer CPL2 may have a refractive index of 1.8 to 2.2 in order to efficiently reflect and transmit internally emitted light. The refractive index of the second capping layer CPL2 may particularly be 1.9 to 2.1. In an embodiment, the refractive index of the second capping layer CPL2 may be 2. The refractive index of the second capping layer CPL2 may be the same as the refractive index of the first capping layer CPL1. In an embodiment, the refractive index of the second capping layer CPL2 may be different from the refractive index of the first capping layer CPL1. However, the present disclosure is not limited thereto, and the refractive index of each of the first capping layer CPL1 and the second capping layer CPL2 can be variously adjusted within the above ranges.

The optical member 300 (see FIG. 2) may be disposed on the counter substrate 200. The optical member 300 may be an anti-reflection member that prevents the reflection of external light.

Referring to FIGS. 9 and 10, the optical member 300 may include a base layer 310, a colorant layer 320, and an adhesive layer 330.

The base layer 310 may include a polymer film. The polymer film may include, for example, any one of polyimide (PI), polyethylene terephthalate (PET), polycarbonate (PC), polyethylene (PE), polypropylene (PP), polysulfone (PSF), polymethyl methacrylate (PMMA), triacetyl cellulose (TAC), and cycloolefin polymer (COP). In an embodiment, the base layer 310 may be triacetyl cellulose.

The colorant layer 320 may be disposed on a surface of the base layer 310. The colorant layer 320 may include colorants that absorb light in specific wavelength bands. The colorant layer 320 may include a first colorant, a second colorant, a third colorant, and a fourth colorant. The first colorant may absorb light in a wavelength band of about 390 to 440 nm. The second colorant may absorb light in a wavelength band of about 490 to 510 nm. The third colorant may absorb light in a wavelength band of about 580 to 610 nm The fourth colorant may absorb light in a wavelength band of about 660 to 690 nm. The first through fourth colorants may transmit light in wavelength bands other than light in the wavelength bands that they absorb.

The colorant layer 320 may transmit blue light having a wavelength band of about 440 to about 490 nm, green light having a wavelength band of about 510 to about 580 nm, and red light having a peak wavelength of about 610 to about 660 nm. The colorant layer 320 may transmit light emitted from the display element layer EVL and absorb light in the above wavelength bands among external light incident from the outside, thereby reducing the reflection of the external light. The colorant layer 320 may be formed by mixing the above colorants in a transparent resin.

The adhesive layer 330 may be disposed on a surface of the colorant layer 320. The adhesive layer 330 may bond the optical member 300 to the counter substrate 200. The adhesive layer 330 may be, for example, a pressure sensitive adhesive (PSA).

FIG. 10 shows a graph of the wavelength dependence of the transmittance of an embodiment of the optical member 300. As illustrated in FIG. 10, the optical member 300 may absorb light in specific wavelength bands and transmit light in other wavelength bands. Accordingly, the optical member 300 may transmit light emitted from the display element layer EVL and absorb light in the above wavelength band among external light incident from the outside, thereby reducing the reflection of the external light. In addition, the optical member 300 may have excellent transmittance when compared to a polarizing plate, and an alignment process, which may be needed when using a polarizing plate to control reflected light, can be omitted when optical member is used.

As described above, the display device 10 according to the embodiment may include the capping layer CPL having the first capping layer CPL1 and the second capping layer CPL2. Therefore, it is possible to reduce the reflection of external light in the non-light emitting area NLA and improve the luminous efficiency of the light emitting areas LA1 through LA3.

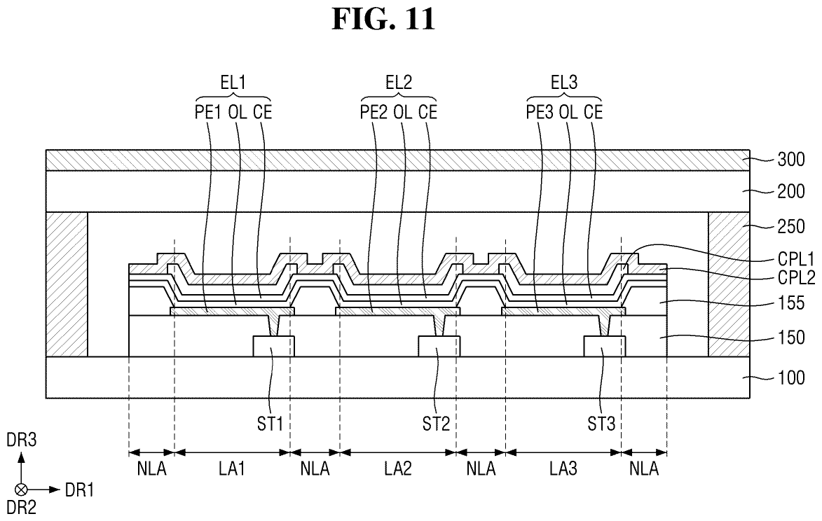

FIG. 11 is a cross-sectional view of a display device according to an embodiment.

Referring to FIG. 11, the current embodiment is different from the embodiment of FIGS. 6 through 10 described above in that it includes a first capping layer CPL1 disposed in each light emitting area LA1, LA2 or LA3 and a second capping layer CPL2 disposed on the first capping layer CPL1 and in the light emitting areas LA1 through LA3 and a non-light emitting area NLA. Therefore, a description of elements and features of the embodiment of FIG. 11 that are identical to those of the above-described embodiment may be omitted, and differences are described below.

A capping layer CPL for the example of FIG. 11 may be disposed on a display element layer EVL and may include the first capping layer CPL1 and the second capping layer CPL2 disposed on the first capping layer CPL1.

The first capping layer CPL1 may be directly disposed on the display element layer EVL. The first capping layer CPL1 may overlap the light emitting areas LA1 through LA3 of the display element layer EVL. Specifically, the first capping layer CPL1 may overlap a first light emitting area LA1, a second light emitting area LA2, and a third light emitting area LA3. The first capping layer CPL1 may not overlap the non-light emitting area NLA of the display element layer EVL. The first capping layer CPL1 may be disposed in the shape of a plurality of islands to correspond to the light emitting areas LA1 through LA3, respectively, and an area between the islands may correspond to the non-light emitting area NLA. In addition, the first capping layer CPL1 may not overlap the bank layer 155.

The first capping layer CPL1 may increase the luminous efficiency of light emitting elements EL1 through EL3 by increasing a thickness of the capping layer CPL in each of the light emitting areas LA1 through LA3. A thickness of the first capping layer CPL1 may be 150 to 350 Å. The first capping layer CPL1 may include an inorganic material or an organic material. In some embodiments, the inorganic material may be an inorganic insulating material or an inorganic deposition material, and the organic material may be an organic insulating material or an organic deposition material. In some embodiments, the inorganic material may include, for example, any one or more of silicon nitride, aluminum oxide, titanium oxide, tantalum oxide, zirconium oxide, and niobium oxide. In some embodiments, the organic material may include any one or more of acrylic resin, methacrylate resin, polyisoprene, vinyl resin, epoxy resin, urethane resin, cellulose resin, and perylene resin.

The first capping layer CPL1 may have a refractive index of 1.8 to 2.2 in order to efficiently reflect and transmit internally emitted light. The refractive index of the first capping layer CPL1 may particularly be 1.9 to 2.1. In an embodiment, the refractive index of the first capping layer CPL1 may be 2.

The second capping layer CPL2 may be disposed on the display element layer EVL and the first capping layer CPL1. The second capping layer CPL2 may cover the display element layer EVL and the first capping layer CPL1. The second capping layer CPL2 may overlap the light emitting areas LA1 through LA3 and the non-light emitting area NLA of the display element layer EVL. For example, the second capping layer CPL2 may be continuously disposed across the light emitting areas LA1 through LA3 and the non-light emitting area NLA.

The second capping layer CPL2 may include an inorganic insulating material that can protect the top of the display element layer EVL. The inorganic insulating material may include, for example, any one or more of silicon nitride, aluminum oxide, titanium oxide, tantalum oxide, zirconium oxide, and niobium oxide. The second capping layer CPL2 may be made of a different inorganic insulating material from the first capping layer CPL1.

The second capping layer CPL2 may have a predetermined thickness to make incident external light disappear through destructive interference. The thickness of the second capping layer CPL2 may be 350 to 450 Å. The second capping layer CPL2 having a thickness of 350 to 450 Å can reduce the reflection of external light incident on the non-light emitting area NLA by making the external light disappear.

The second capping layer CPL2 may have a refractive index of 1.8 to 2.2 in order to reflect external light and efficiently transmit internally emitted light. The refractive index of the second capping layer CPL2 may be the same as the refractive index of the first capping layer CPL1. However, the present disclosure is not limited thereto, and the refractive index of the second capping layer CPL2 can be variously adjusted within the above ranges.

According to an embodiment, the thickness of the capping layer CPL in each of the light emitting areas LA1 through LA3 may be 600 to 700 Å. The thickness of the capping layer CPL in each of the light emitting areas LA1 through LA3 may be the sum of the thickness of the first capping layer CPL1 and the thickness of the second capping layer CPL2. If the thickness of the capping layer CPL in each of the light emitting areas LA1 through LA3 is 600 to 700 Å, a resonance thickness that can cause the resonance phenomenon of the light emitting elements EL1 through EL3 may be formed.

Accordingly, the luminous efficiency of each of the light emitting elements EL1 through EL3 can be increased.

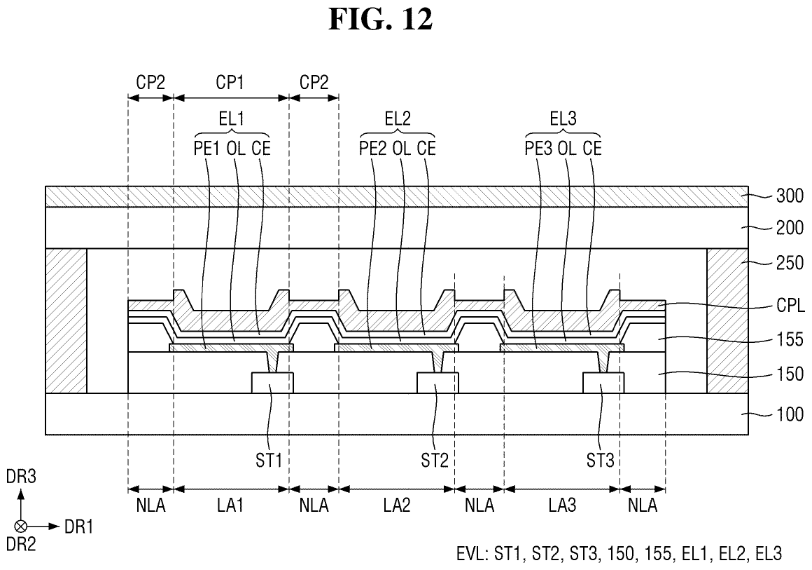

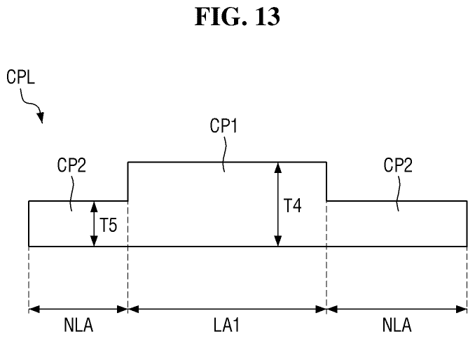

FIG. 12 is a cross-sectional view of a display device according to an embodiment. FIG. 13 is a schematic view of a capping layer CPL according to the embodiment of FIG. 12.

Referring to FIGS. 12 and 13, the current embodiment is different from the embodiments of FIGS. 6 through 11 described above in that the capping layer CPL is a single layer and includes an inorganic insulating material.

The capping layer CPL may be disposed on a display element layer EVL. The capping layer CPL may be a single layer including an inorganic insulating material. The capping layer CPL may be manufactured by depositing an inorganic insulating material on the display element layer EVL and then depositing the same inorganic insulating material on the inorganic insulating material. The process of manufacturing the capping layer CPL is described in more detail below.

As illustrated in FIG. 13, the capping layer CPL may include a first area CP1 and a second area CP2.

The first area CP1 may overlap light emitting areas LA1 through LA3 of the display element layer EVL. Specifically, the first area CP1 may overlap a first light emitting area LA1, a second light emitting area LA2, and a third light emitting area LA3. The first area CP1 may not overlap a non-light emitting area NLA of the display element layer EVL. The first area CP1 may be disposed in the shape of a plurality of islands to correspond to the light emitting areas LA1 through LA3, respectively, and an area between the islands may correspond to the non-light emitting area NLA. In addition, the first area CP1 may not overlap a bank layer 155.

The second area CP2 may overlap the non-light emitting area NLA of the display element layer EVL. The second area CP2 may not overlap the first light emitting area LA1, the second light emitting area LA2, and the third light emitting area LA3. The second area CP2 may be disposed in a mesh shape to correspond to the non-light emitting area NLA, and areas defined by the mesh shape may correspond to the light emitting areas LA1 through LA3, respectively. In addition, the second area CP2 may overlap the bank layer 155.

The first area CP1 may have a thickness T4 of 600 to 700 Å in order to increase the luminous efficiency of light emitting elements EL1 through EL3 corresponding to the light emitting areas LA1 through LA3, respectively. The second area CP2 may have a thickness T5 of 350 to 450 Å in order to reduce the reflection of external light in the non-light emitting area NLA. The thickness T4 of the first area CP1 may be greater than the thickness T5 of the second area CP2. A difference between the thickness T4 of the first area CP1 and the thickness T5 of the second area CP2 may be 150 to 350 Å.

In an embodiment, an uppermost surface of the first area CP1 of the capping layer CPL may be disposed adjacent to a counter substrate 200. Here, the uppermost surface may be a surface disposed highest from a substrate 100 in the third direction DR3. The uppermost surface of the first area CP1 may be disposed closer to the counter substrate 200 than an uppermost surface of the second area CP2. In addition, at least a portion of the upper surface of the first area CP1 may be concave toward the substrate 100.

In the current embodiment, since the capping layer CPL including the first area CP1 overlapping each of the light emitting areas LA1 through LA3 and the second area CP2 overlapping the non-light emitting area NLA is formed, it is possible to reduce the reflection of external light in the non-light emitting area NLA and improve luminous efficiency in the light emitting areas LA1 through LA3.

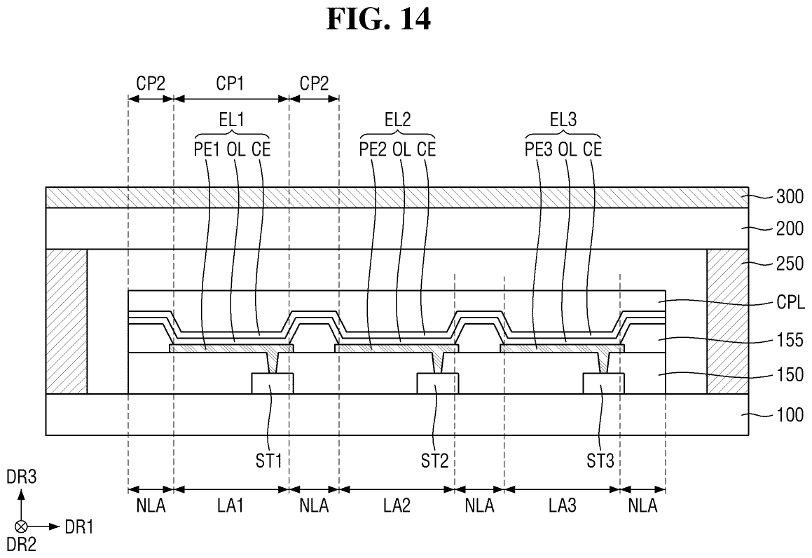

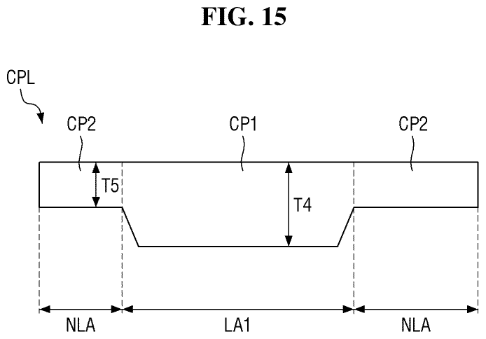

FIG. 14 is a cross-sectional view of a display device according to an embodiment. FIG. 15 is a schematic view of a capping layer CPL according to the embodiment of FIG. 14.

Referring to FIGS. 14 and 15, the current embodiment is different from the embodiments of FIGS. 6 through 11 in that the capping layer CPL is a single layer of organic material. The embodiment of FIGS. 14 and 15 differs from the embodiment of FIGS. 12 and 13 in that the capping layer CPL in the embodiment of FIGS. 14 and 15 has a flatter uppermost surface.

The capping layer CPL may be disposed on a display element layer EVL. The capping layer CPL may be a single layer including an organic insulating material. The capping layer CPL may be manufactured by applying an organic insulating material on the display element layer EVL using a solution process.

As illustrated in FIG. 15, the capping layer CPL may include a first area CP1 and a second area CP2. Since the arrangement of the first area CP1 and the second area CP2 is the same as that in FIGS. 12 and 13, a description thereof will be omitted.

The first area CP1 may have a thickness T4 of 600 to 700 Å in order to increase the luminous efficiency of light emitting elements EL1 through EL3 corresponding to light emitting areas LA1 through LA3, respectively. The second area CP2 may have a thickness T5 of 350 to 450 Å in order to reduce the reflection of external light in a non-light emitting area NLA. The thickness T4 of the first area CP1 may be greater than the thickness T5 of the second area CP2. A difference between the thickness T4 of the first area CP1 and the thickness T5 of the second area CP2 may be 150 to 350 Å.

In an embodiment, an upper surface of the capping layer CPL may be flat. For example, the upper surface of the capping layer CPL may be disposed parallel to an upper surface of a substrate 100. Accordingly, an upper surface of the first area CP1 and an upper surface of the second area CP2 may be aligned with each other. A lowermost surface of the first area CP1 may be disposed adjacent to the substrate 100. Here, the lowest surface may be a surface disposed lowest from a counter substrate 200 in a direction opposite to the third direction DR3. The lowermost surface of the first area CP1 may be disposed closer to the substrate 100 than a lowermost surface of the second area CP2. In addition, at least a portion of the lower surface of the first area CP1 may extend downward toward the substrate 100.

In the current embodiment, since the capping layer CPL includes the first area CP1 overlapping each of the light emitting areas LA1 through LA3 and the second area CP2 overlapping the non-light emitting area NLA, it is possible to reduce the reflection of external light in the non-light emitting area NLA and improve luminous efficiency in the light emitting areas LA1 through LA3.

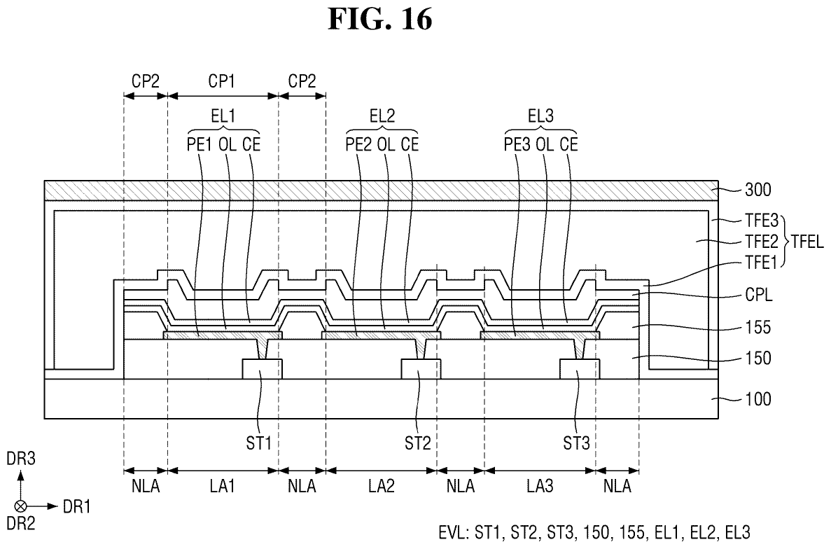

FIG. 16 is a cross-sectional view of a display device according to an embodiment.

Referring to FIG. 16, the current embodiment is different from the embodiments of FIGS. 6 through 15 in that a counter substrate 200 and a sealing member 250 are omitted and that a thin-film encapsulation layer TFEL is disposed on a capping layer CPL.

A display element layer EVL may be disposed on a substrate 100, and the capping layer CPL may be disposed on the display element layer EVL. The capping layer CPL may be any of the capping layers CPL described above with reference to FIGS. 6 through 15. The thin-film encapsulation layer TFEL may be disposed on the capping layer CPL, and an optical member 300 may be disposed on the thin-film encapsulation layer TFEL.

The thin-film encapsulation layer TFEL may be commonly located in a first light emitting area LA1, a second light emitting area LA2, a third light emitting area LA3, and a non-light emitting area NLA. In an embodiment, the thin-film encapsulation layer TFEL may directly cover the capping layer CPL and may cover the display element layer EVL.

In an embodiment, the thin-film encapsulation layer TFEL may include a first encapsulating inorganic layer TFE1, an encapsulating organic layer TFE2, and a second encapsulating inorganic layer TFE3 sequentially stacked on the capping layer CPL.

The first encapsulating inorganic layer TFE1 and the second encapsulating inorganic layer TFE3 may each include any one or more of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulating organic layer TFE2 may include acrylic resin, methacrylate resin, polyisoprene, vinyl resin, epoxy resin, urethane resin, cellulose resin, or perylene resin.

The structure of the thin-film encapsulation layer TFEL is not limited to the above-described examples, and the stacked structure of the thin-film encapsulation layer TFEL can be variously changed.

In the display device 10 illustrated in FIG. 16, the substrate 100 may be a rigid substrate or a flexible substrate. Accordingly, the display device 10 may be a rigid display device or a foldable display device that can be folded and unfolded.

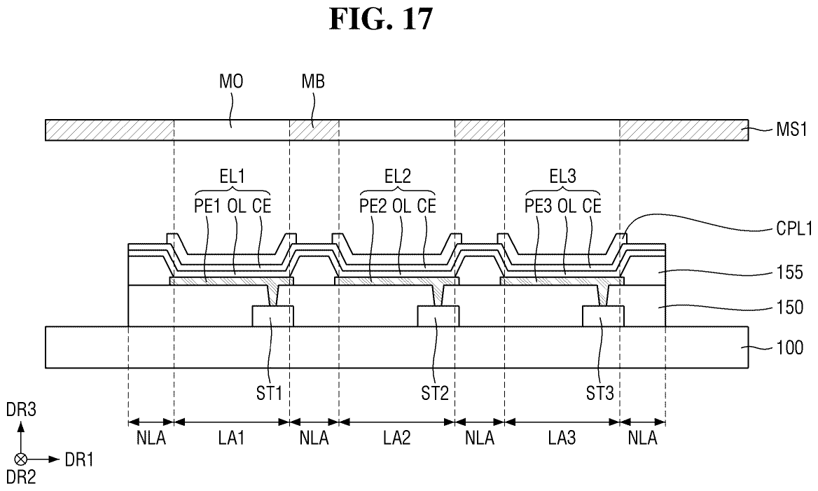

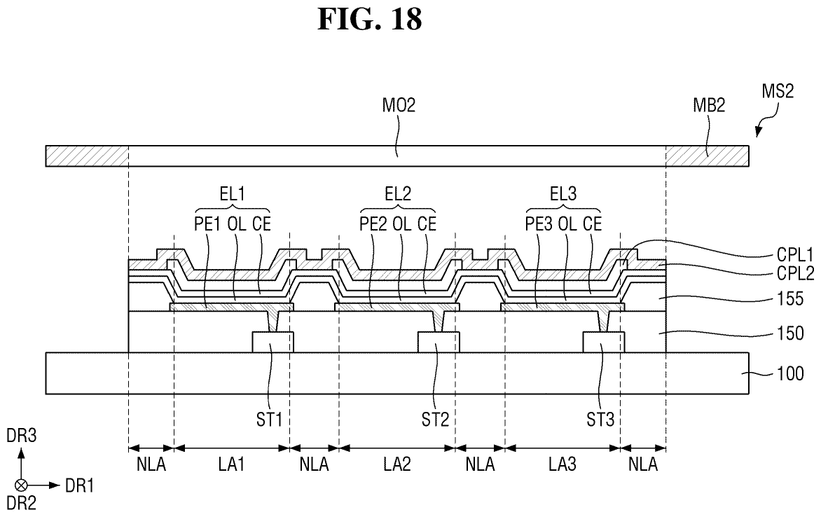

FIGS. 17 and 18 are cross-sectional views illustrating a method of manufacturing a display device according to an embodiment. FIGS. 17 and 18 schematically particularly illustrate a process of manufacturing the capping layer CPL of the display device of FIG. 11 described above.

Referring to FIG. 17, a display element layer EVL is formed by forming a plurality of switching elements ST1 through ST3, a plurality of light emitting elements EL1 through EL3, a via layer 150, and a bank layer 155 on a substrate 100.

Next, the substrate 100 is inverted, and a first mask MS1 is aligned to correspond to a surface of the substrate 100. The first mask MS1 may be placed to face the display element layer EVL. The first mask MS1 may include opening areas MO and a blocking area MB. The opening areas MO may be areas through which a deposition material passes, and the blocking area MB may be an area through which the deposition material cannot pass but is blocked. The opening areas MO may be placed to correspond to light emitting areas LA1 through LA3 of the display element layer EVL, respectively, and the blocking area MB may be placed to correspond to a non-light emitting area NLA.

Next, a first capping layer CPL1 is formed by depositing an inorganic insulating material on the substrate 100 on which the first mask MS1 is aligned. The deposition process may use chemical vapor deposition (CVD) or physical vapor deposition (PVD). A portion of the inorganic insulating material may be deposited on each of the light emitting areas LA1 through LA3 of the display element layer EVL through an opening area MO of the first mask MS1. The other portion of the inorganic insulating material may not be deposited on the non-light emitting area NLA of the display element layer EVL because the blocking area MB of the first mask MS1 blocks deposition onto the non-light emitting area NLA. Therefore, the first capping layer CPL1 may be formed on each of the light emitting areas LA1 through LA3 of the display element layer EVL.

Next, referring to FIG. 18, a second mask MS2 is aligned to correspond to the surface of the substrate 100. The second mask MS2 may be placed to face the display element layer EVL. The second mask MS2 may include an opening area MO2 and a blocking area MB2. The opening area MO2 may be placed to correspond to the light emitting areas LA1 through LA3 and the non-light emitting area NLA of the display element layer EVL, and the blocking area MB may be placed to correspond to areas other than the display element layer EVL.

Next, a second capping layer CPL2 is formed by depositing an inorganic insulating material on the substrate 100 on which the second mask MS2 is aligned. A portion of the inorganic insulating material may be deposited on the light emitting areas LA1 through LA3 and the non-light emitting area NLA of the display element layer EVL through the opening area MO2 of the second mask MS2. The deposition of the other portion of the inorganic insulating material may be blocked by the blocking area MB2 of the second mask MS2. Therefore, the second capping layer CPL2 may be formed on the light emitting areas LA1 through LA3 and the non-light emitting area NLA of the display element layer EVL.

Next, the substrate 100 and a counter substrate 200 may be bonded together, and an optical member 300 may be attached to a surface of the counter substrate 200 to produce the display device 10 illustrated in FIG. 11.

Hereinafter, simulation examples of the display device 10 described above will be described.

### Simulation 1

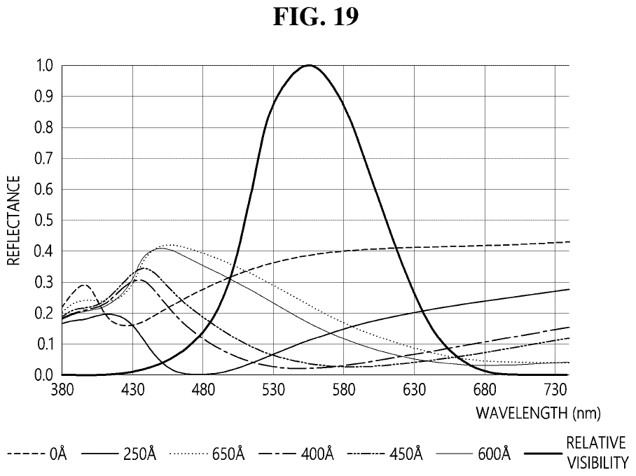

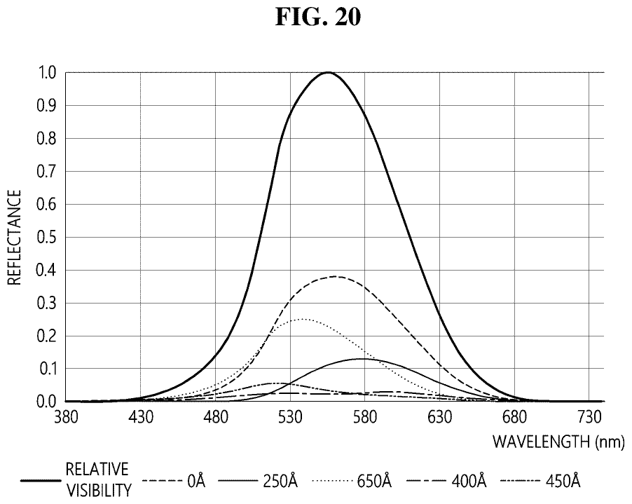

In a structure in which a bank layer, a hole transport layer, an electron transport layer, and a common electrode are stacked on a substrate, the reflectance of the substrate and reflectance according to the thickness of a capping layer on the common electrode were simulated by varying the thickness of the capping layer to 250 Å, 400 Å, 450 Å, 600 Å, and 650 Å. Here, the reflectance showed results that reflected relative visibility and results that did not reflect relative luminous efficiency. In addition, the common electrode that affects reflectance was set to 95 Å AgMg. The simulations results are shown in FIGS. 19 and 20.

FIG. 19 is a graph illustrating reflectance with respect to wavelength. FIG. 20 is a graph illustrating relative luminous efficiency-reflected reflectance with respect to wavelength. In FIGS. 19 and 20, the horizontal axis represents wavelength, the vertical axis represents reflectance, and each plot represents the thickness of the capping layer.

Referring to FIG. 19, the reflectance was relatively lower when the capping layer was provided than when the capping layer was not provided. In particular, as the thickness of the capping layer decreased from 650 Å to 250 Å, the overall reflectance decreased.

Referring to FIG. 20, when the relative luminous efficiency was reflected, the reflectance was relatively lower when the capping layer was provided than when the capping layer was not provided. In particular, the reflectance was significantly lower when the thickness of the capping layer was 400 Å and 450 Å.

### Simulation 2

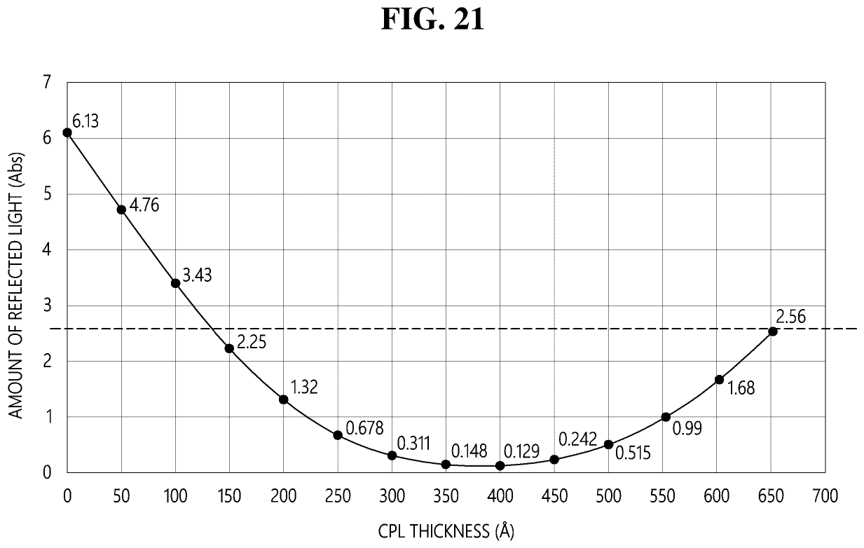

In a structure in which a bank layer, a hole transport layer, an electron transport layer, a common electrode, and a capping layer are stacked on a substrate, the amount of reflected light was simulated by varying the thickness of the capping layer within the range of 0 to 650 Å. These simulation results are shown in Table 1 and FIG. 21.

FIG. 21 is a graph illustrating the amount of reflected light with respect to the thickness of the capping layer. In FIG. 21, the horizontal axis represents the thickness of the capping layer, and the vertical axis represents the amount of reflected light.

TABLE 1

| | | Ratio of Amount of |
|---|---|---|
| | | Reflected Light according |
| | | to Thickness of Capping |
| | | Layer to Amount of |
| | | Reflected Light When |
| Thickness of | Amount of | Thickness of Capping |
| Capping Layer (Å) | Reflected Light | Layer is 650 Å |
| 0 | 6.13 | 2.39 |
| 50 | 4.76 | 1.86 |
| 100 | 3.43 | 1.34 |
| 150 | 2.25 | 0.88 |
| 200 | 1.32 | 0.52 |
| 250 | 0.678 | 0.26 |
| 300 | 0.311 | 0.12 |
| 350 | 0.148 | 0.06 |
| 400 | 0.129 | 0.05 |
| 450 | 0.242 | 0.09 |
| 500 | 0.515 | 0.20 |
| 550 | 0.99 | 0.39 |
| 600 | 1.68 | 0.66 |
| 650 | 2.56 | 1.00 |

Referring to Table 1 and FIG. 21, when the thickness of the capping layer was 400 Å, the amount of reflected light was 0.129 which was the lowest, and when the thickness of the capping layer was 650 Å, the amount of reflected light was 2.56.

As is apparent from the above results, the amount of reflected light was reduced by about 95% when the thickness of the capping layer was 400 Å compared to when the thickness of the capping layer was 650 Å.

Therefore, in the current embodiment, the reflection of external light can be reduced as much as possible by forming a capping layer having a thickness of about 350 to 450 Å in a non-light emitting area. In addition, the luminous efficiency of a light emitting element can be maximized by forming a capping layer having a thickness of about 600 to 700 Å in a light emitting area.

In a display device according to an embodiment, a capping layer having different thicknesses in a light emitting area and a non-light emitting area is formed. Therefore, it is possible to reduce the reflection of external light in the non-light emitting area and improve luminous efficiency in the light emitting area.

In addition, since the display device further includes an optical member, the reflection of external light can be reduced, and a polarizing plate can be omitted.

However, the effects of the present disclosure are not restricted to those set forth herein. The above and other effects of the present disclosure will become more apparent to one of skill in the art to which the present disclosure pertains by referencing the claims.

In concluding the detailed description, those skilled in the art will appreciate that many variations and modifications can be made to the example embodiments without substantially departing from the principles of the present disclosure. Therefore, the disclosed example embodiments are used in a generic and descriptive sense only and not for purposes of limitation.

What is claimed is:

1. A display device comprising:
a pixel electrode disposed on a substrate;
a bank layer covering edges of the pixel electrode and defining light emitting areas and a non-light emitting area;
a light emitting layer disposed on the pixel electrode and the bank layer;
a common electrode disposed on the light emitting layer;
a capping layer disposed on the common electrode;
a counter substrate facing the substrate; and
an optical member disposed on the counter substrate,
wherein the capping layer comprises:
a first capping layer disposed on the common electrode; and
a second capping layer disposed on the first capping layer and overlapping the light emitting areas.

2. The display device of claim 1, wherein the first capping layer overlaps the light emitting areas and the non-light emitting area and overlaps the second capping layer.

3. The display device of claim 1, wherein a thickness of the first capping layer is 350 to 450 Å.

4. The display device of claim 1, wherein a refractive index of each of the first capping layer and the second capping layer is 1.8 to 2.2.

5. The display device of claim 1, wherein a thickness of the second capping layer is 150 to 350 Å.

6. The display device of claim 1, wherein the first capping layer and the second capping layer comprise different materials.

7. The display device of claim 1, wherein the sum of the thicknesses of the first capping layer and the second capping layer in each of the light emitting areas is 600 to 700 Å.

8. The display device of claim 1, wherein the first capping layer is disposed under the second capping layer or on the second capping layer.

9. The display device of claim 1, wherein the optical member comprises:
a base layer;
a colorant layer disposed on the base layer; and
an adhesive layer disposed on the colorant layer.

10. The display device of claim 9, wherein the colorant layer transmits light in a wavelength band of 440 to 490 nm, a wavelength band of 510 to 580 nm, and a wavelength band of 610 to 660 nm and absorbs light in other wavelength bands.

11. A display device comprising:
a pixel electrode disposed on a substrate;
a bank layer covering edges of the pixel electrode and defining light emitting areas and a non-light emitting area;
a light emitting layer disposed on the pixel electrode and the bank layer;
a common electrode disposed on the light emitting layer;
a capping layer disposed on the common electrode;
a counter substrate facing the substrate; and
an optical member disposed on the counter substrate,
wherein the capping layer comprises a first area overlapping the light emitting areas and a second area overlapping the non-light emitting area, and a thickness of the first area is greater than a thickness of the second area.

12. The display device of claim 11, wherein the thickness of the first area is 600 to 700 Å.

13. The display device of claim 11, wherein the thickness of the second area is 350 to 450 Å.

14. The display device of claim 11, wherein the first area does not overlap the non-light emitting area, and the second area does not overlap the light emitting areas.

15. The display device of claim 11, wherein the capping layer comprises an inorganic insulating material or an organic insulating material.

16. The display device of claim 11, wherein an upper surface of the capping layer is flat and disposed parallel to the substrate.

17. A display device comprising:
a pixel electrode disposed on a substrate;
a bank layer covering edges of the pixel electrode and defining light emitting areas and a non-light emitting area;
a light emitting layer disposed on the pixel electrode and the bank layer;
a common electrode disposed on the light emitting layer;
a capping layer disposed on the common electrode;
a thin-film encapsulation layer disposed on the capping layer; and
an optical member disposed on the thin-film encapsulation layer,
wherein the capping layer comprises a first area overlapping the light emitting areas and a second area overlapping the non-light emitting area, and a thickness of the first area is greater than a thickness of the second area.

18. The display device of claim 17, wherein the thin-film encapsulation layer comprises a first encapsulating inorganic layer disposed on the capping layer, an encapsulating organic layer disposed on the first encapsulating inorganic layer, and a second encapsulating inorganic layer disposed on the encapsulating organic layer.

19. The display device of claim 17, wherein the first area does not overlap the non-light emitting area, and the second area does not overlap the light emitting areas.

20. The display device of claim 17, wherein the optical member comprises:
a base layer;
a colorant layer disposed on the base layer; and
an adhesive layer disposed on the colorant layer,
wherein the colorant layer transmits light in a wavelength band of 440 to 490 nm, a wavelength band of 510 to 580 nm and a wavelength band of 610 to 660 nm and absorbs light in other wavelength bands.
